(19) United States
(12) Patent Application Publication
(10) Pub. No.: US 2026/0063719 A1
(43) Pub. Date: Mar. 5, 2026

(54) Computer implemented method and system for anomaly detection in industrial drivetrain

(71) Applicant: Insens SRL, Louvian-la-neuve (BE)

(72) Inventors: Nicolas Verbeek, Louvian-la-neuve (BE); Thomas de Mondesir, Louvian-la-neuve (BE); Guillaume Francaux, Louvian-la-neuve (BE); Gautier Waterlot, Louvian-la-neuve (BE)

(73) Assignee: Insens SRL, Louvian-la-neuve (BE)

(21) Appl. No.: 18/817,304

(22) Filed: Aug. 28, 2024

(51) Int. Cl. G01R 31/34; G01H 11/06; G01R 19/25; G01R 23/18

(52) U.S. Cl. CPC G01R 31/343; G01H 11/06; G01R 19/2509; G01R 23/18

(57) ABSTRACT

A system for anomaly detection in an industrial drivetrain comprising various mechanical elements driven by a three-phase electrical motor. The system comprises a sensor system for obtaining electrical current and voltage waveform data by measuring electrical currents and voltages at the three-phase motor, and a computing system. The electrical waveform data contains frequency components relating to vibrations of mechanical elements of the drivetrain. The computing system performs the following steps: processing the electrical waveform data to obtain related frequency spectra, thereby enhancing traceability of the frequency components; combining the frequency spectra into a combined frequency spectrum, thereby further enhancing traceability of the frequency components; forming a spectrogram by monitoring the combined frequency spectrum over time; and tracing the frequency components in the spectrogram for anomaly detection of the related mechanical elements of the industrial drivetrain.

### FIELD OF THE DISCLOSURE

The present disclosure relates to a system and computer implemented method for anomaly detection (e.g. fault detection) in an industrial drivetrain that is driven by an electric motor.

### BACKGROUND ART

Today, there is an increasing need in industry to monitor rotating machinery by electronic means to optimize operation, detect anomalies and predict maintenance faults to prevent or reduce downtime. Any downtime, especially unplanned, may lead to important financial losses. Traditional methods of monitoring the condition of rotating machinery include vibration analysis using accelerometers mounted on or near the mechanical elements of the drivetrain that are driven by the three-phase electric motor. These methods may require a large number of sensors, which furthermore need to be deployed in a vast production environment, which may be a dirty, hazardous or controlled environment. On the other hand, there are some documents that disclose an analysis of electrical signals, in particular stator currents, in order to evaluate the state of rotating machinery connected to a three-phase electric motor.

From U.S. Pat. No. 10,393,621, a method and a computer program for assessing the condition of rotating machinery connected to an electric motor are known. The motor and the rotating machinery comprise a drivetrain electrically powered from a three-phase motor and the motor is connected with a computing device. The method comprises the step of classifying the condition of rotating machinery with unknown conditions, by analyzing all the extracted representative features obtained from the electric signals acquired from the electric motor and by using a trained neural network.

U.S. Pat. No. 10,928,814 discloses systems and methods for performing an autonomous procedure for monitoring and diagnostics of a machine using electrical signature analysis. One method includes providing electrical data of an electrical rotating machine associated with at least one fault frequency. While in a learning mode, the method includes converting the electrical data from a time domain to a frequency domain to obtain baseline data. While in an operational mode, the method includes converting the electrical data from the time domain to the frequency domain to obtain monitoring data. The method further includes determining, based at least on the monitoring data, a ratio value at the fault frequency, determining a rate of change of the ratio value at the fault frequency, and, optionally, issuing, based on the rate of change, an alarm concerning at least one event of the electrical rotating machine.

US20230057924A1 discloses systems and methods for improved anomaly detection for rotating machines. One method includes determining a rotational speed of a rotating machine; determining, using a frequency domain transform of a signal, a frequency domain signal; determining, based on the rotational speed, a first frequency band within the frequency domain signal for identifying a fault frequency; determining a fault frequency within the first frequency band; determining, based on the fault frequency, a second frequency band within the first frequency band, wherein the second frequency band includes the fault frequency; determining, based on the second frequency band, a first fault index and a baseline of the first fault index; determining, based on a deviation of a second fault index from the baseline, a fault condition; and providing an alert based on the fault condition.

### SUMMARY OF THE DISCLOSURE

It is an aim of the present disclosure to provide an alternative and/or improved computer implemented method and system for anomaly detection in an industrial drivetrain, based on analysis of electrical signals captured at the electric motor.

In an aspect, which may be combined with other aspects and/or embodiments described herein, the present disclosure relates to a system for anomaly detection in an industrial drivetrain, wherein the industrial drivetrain comprises various mechanical elements and is driven by a three-phase electrical motor. The system comprises a sensor system for obtaining electrical current and voltage waveform data by measuring electrical currents and voltages at the three-phase motor, the electrical current and voltage waveform data containing a predefined set of frequency components relating to vibrations of a number of said mechanical elements during operation of the drivetrain; and a computing system. The computing system is configured for performing the following steps: processing the electrical current and voltage waveform data to obtain a number of frequency spectra related to the waveform data, wherein the processing comprises steps for enhancing traceability of the frequency components in said frequency spectra; combining the frequency spectra to a combined frequency spectrum, wherein the combining step further enhances traceability of the frequency components in the combined frequency spectrum; forming a spectrogram by monitoring the combined frequency spectrum over time; and detecting anomalies of the predefined set of frequency components in the spectrogram, whereby anomalies in the operation of the related mechanical elements of the industrial drivetrain are detected.

In an aspect, which may be combined with other aspects and/or embodiments described herein, the present disclosure relates to a computer implemented method for anomaly detection in an industrial drivetrain, which may comprise various mechanical elements that are driven by a three-phase electrical motor. The computer implemented method comprises the steps of: obtaining electrical current and voltage waveform data from a sensor unit measuring electrical currents and voltages at or near the three-phase motor, the electrical current and voltage waveform data containing a predefined set of frequency components that are related with vibrations of a number of the mechanical elements during operation of the drivetrain; processing the electrical current and voltage waveform data to obtain a number of frequency spectra related to the waveform data, wherein the processing comprises steps for enhancing traceability of the frequency components in said frequency spectra; combining the frequency spectra to a combined frequency spectrum, wherein the combining step further enhances traceability of the frequency components in the combined frequency spectrum; forming a spectrogram by monitoring the combined frequency spectrum over time; and detecting anomalies of the predefined set of frequency components in the spectrogram, whereby anomalies in the operation of the related mechanical elements of the industrial drivetrain are detected.

The spectrogram, being based on the raw waveform data, is representative of a multitude of frequency components captured or detected in the raw waveform data. Hence, the spectrogram may be considered a kind of signature of the rotating machinery and hence be termed a machine-spectrogram. The inventors have found that one or more predefined frequency components, for which a relationship with mechanical elements of the drivetrain can be determined, may be traced in such a machine-spectrogram and that thereby anomalies (e.g. faults) may be detected and/or predicted. In this way, the detection and/or prediction of the anomalies may be used for purposes of preventive or predictive maintenance of the mechanical elements of drivetrain, or the like.

The inventors have found that the tracing of the frequency components may be facilitated or enhanced by a specific sequence of steps, namely first processing the electrical current and voltage waveform data and transforming this data into related frequency spectra while enhancing traceability of the frequency components, and subsequently combining the obtained frequency spectra into the spectrogram. In the processing step(s), the traceability of the frequency components may be enhanced by transforming the data to the frequency domain and applying steps such as filtering, amplification and/or attenuation to improve a signal to noise ratio of at least one of the frequency components. The step of combining the frequency spectra into one combined frequency spectrum may further improve the traceability of the frequency components. For example, some of the frequency spectra may overlap so that one or more of the frequency components may be amplified in the combined frequency spectrum. Thus, the processing and combination steps may contribute in a synergetic way to enhance the traceability of the frequency components in the combined frequency spectrum and consequently also in the spectrogram.

In embodiments according to the present disclosure, the computing system may be at least partially integrated with the sensor system in a sensor unit that is located at or near the three-phase motor. In other words, the sensor unit may comprise the sensor system as well as processing means or components configured for performing one or more of the processing steps.

In embodiments according to the present disclosure, the computing system may be a remote computing system and the sensor system may be provided for communicating with the remote computing system.

In embodiments according to the present disclosure, the obtained frequency spectra may at least partially overlap and the step of combining the frequency spectra to the combined frequency spectrum may amplify at least some of the frequency components.

In embodiments according to the present disclosure, the frequency components may relate to vibrations caused by one or more of the following group of mechanical elements: couplings such as a V-belt, a timed belt, a chain, a cardan joint, a rigid coupling, a flexible coupling, a jaw coupling, a magnetic coupling or other coupling element; single- and multi-staged gearboxes; mechanical loads such as a pump, a submersible pump, a compressor, a ventilator, a mixer, a conveyor belt, a crusher, an elevator, a vibrating screen, a worm screw, a blower, or other mechanical load element.

In embodiments according to the present disclosure, the processing steps may comprise one or more of the following: direct quadrature zero transformation; direct Fourier transformation; Hilbert transform; filtering, amplification and/or attenuation to improve a signal to noise ratio of at least one of the frequency components; data compression steps for removing less significant data.

In embodiments according to the present disclosure, the processing steps may comprise computation of one or more scalar metrics. In embodiments, the processing steps may comprise one or more steps for augmenting the combined frequency spectrum based on the one or more scalar metrics. In embodiments, the scalar metrics may comprise at least one of: active power, reactive power, line frequency, switching frequency.

In embodiments according to the present disclosure, one or more data compression steps may be performed for compression of the spectrogram, preferably wherein the spectrogram is compressed by means of a lossy compression algorithm.

In embodiments according to the present disclosure, the step of detecting anomalies comprises tracing the predefined set of frequency components in the spectrogram.

In embodiments according to the present disclosure, the step of tracing the frequency components in the spectrogram comprises: detecting and tracing a motor rotational speed of the electrical motor in the spectrogram, determining a frequency ratio of each of the predefined set of frequency components with respect to the motor rotational speed, and tracing the frequency components based on the determined frequency ratios.

In embodiments according to the present disclosure, the method further comprises the following steps for the anomaly detection: comparing traced values of the traced frequency components with predicted values of the frequency components, calculating an anomaly score based on the comparison and triggering an alert if the anomaly score meets predetermined conditions.

In embodiments according to the present disclosure, the step of detecting anomalies comprises using a machine learning model on the spectrogram, preferably a trained autoencoder.

In embodiments according to the present disclosure, the machine learning model is used to predict values for the predefined set of frequency components, and wherein the method further comprises comparing the predicted values with actual values of the predefined set of frequency components, calculating an anomaly score based on the comparison and triggering an alert if the anomaly score meets predetermined conditions.

In an aspect, which may be combined with other aspects and/or embodiments described herein, the present disclosure relates to a computer program product for performing the computer implemented method as disclosed herein.

In embodiments, the computer program product may comprise a non-transitory computer-readable medium containing code in a computer executable format which when executed on a computing system triggers the computing system to perform the computer-implemented method as disclosed herein.

### BRIEF DESCRIPTION OF THE DRAWINGS

Embodiments of the present disclosure will be discussed in more detail below, with reference to the attached drawings.

FIG. 1 shows a schematic view of an industrial system comprising rotating machinery according to the present disclosure.

FIG. 2 schematically shows examples of frequency components, relating to mechanical elements, which may be detectable and traceable by means of methods according to the present disclosure.

FIG. 3 shows a graphic example of an anomaly detectable by means of methods according to the present disclosure.

FIGS. 4-7 show flowcharts of embodiments of computer implemented methods according to the present disclosure.

FIG. 8 shows, for a practical example, an example of frequency spectra obtained by transformations preformed the voltage and current waveform data.

FIG. 9 shows, for the practical example, a portion of a machine-spectrogram obtained by combining frequency spectra as shown in FIG. 8 and monitoring them over time.

FIG. 10 shows, for the practical example, a portion of a machine-spectrogram with a healthy part and an anomaly.

FIG. 11 shows, for the practical example, a reconstructed spectrogram outputted by a trained autoencoder.

FIG. 12 shows, for the practical example, a graph of a reconstruction error calculated by comparing the machine-spectrogram and the reconstructed spectrogram.

### DESCRIPTION OF EMBODIMENTS

Below, particular embodiments according to the disclosure are described with reference to certain drawings but the disclosure is not limited thereto. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

The terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

The terms top, bottom, over, under and the like in the description and the claims are used for descriptive purposes and not necessarily for describing relative positions. The terms so used are interchangeable under appropriate circumstances and the embodiments of the disclosure described herein can operate in other orientations than described or illustrated herein.

Furthermore, the various embodiments, although referred to as “preferred” are to be construed as exemplary manners in which the disclosure may be implemented rather than as limiting the scope of the disclosure.

The present disclosure provides systems and computer implemented methods that may allow to detect and/or predict failures occurring on rotating machinery, in particular anomalies or failures on mechanical elements of a drivetrain that is driven by a three-phase electric motor, based on the analysis of electrical signals that are captured at or near the motor. FIG. 1 schematically shows an embodiment of such a system 100, comprising a drivetrain 104 that is driven by a three-phase motor 102, together forming the rotating machinery of the system. The electrical signals (e.g. stator voltages and currents) at the electric motor may be captured periodically by a sensor system 101 during a data collection process and sent to a remote computing system (not shown), which may for example be a central server of the factory, or any remote server or cloud-based computing system, where the raw signals may be processed and transformed into augmented frequency spectra. The sensor system 101 is preferably located in a control cabinet 103 associated with the motor 102 and the drivetrain 104, or in any case at or near the motor 102. In this way, the need for deploying sensors in the production environment, which may be a dirty, hazardous or controlled environment, may be avoided.

In embodiments, the captured electrical signals may be communicated as raw data from the sensor system 101 to the remote computing system. In other embodiments, some local processing may be performed at the sensor system before transmission to the remote computing system. In the following, embodiments of computer implemented methods according to the disclosure are described, in particular with reference to FIGS. 4-7. One or more of the described steps may be performed locally in the sensor system 101.

In the computer implemented methods according to the disclosure, the captured electrical signals at the electric motor, i.e. voltage and current waveforms are processed in order to obtain augmented frequency spectra. All the (successive) augmented spectra, taken over time, for a single motor may be assembled to form a spectrogram, which may be representative of a multitude of frequency components captured or detected in the raw waveform data. Hence, the spectrogram may be considered a kind of signature of the rotating machinery and hence be termed a machine-spectrogram. The inventors have found that one or more predefined frequency components, which are determined to be related to mechanical elements of the drivetrain, may be traced in such a machine-spectrogram and that thereby anomalies may become detectable. The tracing of the frequency components may involve a kind of compression algorithm to reduce the dimensionality of the data. For example, a physical approach or a data-centric approach may be used for the tracing and detection of anomalies. In embodiments, a prediction may be made on the basis of a historical set of compressed data. This prediction may then be used as a basis to determine if the mechanical elements of the drivetrain exhibit anomalous behavior, for example by determining an anomaly score. If the anomaly score exceeds a certain threshold, the system may detect or predict that a failure is or may be occurring on the machine, and an alert may be triggered.

Possible anomalies that may be detected by means of systems and methods according to the disclosure may basically relate to any mechanical elements of a drivetrain 104 that cause a detectable vibration, that propagates to the rotor of the three-phase electrical motor 102 and consequently becomes a detectable frequency component in the captured electrical signals, captured by the sensor system 101. Examples of such mechanical elements are bearings, belts, chains, gears, gearboxes, cardan joints, flexible couplings, magnetic couplings, rotating elements of mechanical loads such as pumps, ventilators, mixers, conveyor belts, compressors, etc. It has been found that anomalies, such as wear or damage to such mechanical elements or misalignment between mechanical elements, may cause a detectable change in the (normal) vibration or related frequency component and that such changes may be detected by means of the electrical signals captured by the sensor system 101. Each of these mechanical elements may have one or multiple failure modes that may lead to a partial or complete failure of the drivetrain and/or the motor, and the embodiments of the disclosure may be used to detect or prevent such failures.

### Sensor System

The sensor system 101 measures the three-phase electrical signals provided at the input of the motor, i.e. stator voltages and currents. The sensor system may be mounted in a control cabinet 103 of the motor and may be connected to the remote computing system through a wired or wireless network. The sensor system may comprise a combination of voltage and current sensors for measuring the individual voltages between the phases and the individual currents through the phases, and conversion means for converting the measured signals into waveform data. The analog and digital components for these functionalities may be integrated into a unit with various inputs for connecting the voltage and current measuring nodes and telecommunication means for communicating the raw data to the remote computing system, as for example shown in FIG. 1. The unit may further comprise local processing means. In embodiments, multiple sensor systems, each connected to a respective motor and related drivetrain, may be connected through the network(s) to one and the same remote computing system.

In embodiments, the raw three-phase measurements may be sent from the sensor system through the network to remote computing system, where all subsequent operations are then performed. In other embodiments, all operations up to the combined or augmented spectrum may be performed by local processing means on the sensor system, and the combined or augmented spectrum is sent from the sensor system through the network to remote computing system, where all subsequent operations are then performed. In yet other embodiments, all operations up to the compression stage may be performed locally on the sensor system and the compressed spectrogram sent from the sensor system through the network to the remote computing system, where all subsequent operations are performed. In still other embodiments, all operations may be performed locally on the sensor system and only the anomaly score is sent from the sensor system through the network to the remote computing system.

### Machine Metadata

In the various steps of the methods disclosed herein, machine metadata may be used. This term is used herein to refer to e.g. nameplate information of the electric motor, manufacturer information about the drivetrain components and the like, relative rotation speed of the rotating elements (e.g. by use of transmission ratios), etc. In general, the machine metadata may be any additional data about the particular electric motor 102 and its related drivetrain 104 that is not directly collected by the sensor system 101 and provides context. The metadata is static, i.e. does not evolve over time. It may provide information about the manufacturing and capabilities of the electric motor and its related drivetrain as well as the process they have been made to follow. The metadata may include motor nameplate information, as well as a list of all drivetrain elements along with their theoretical frequencies of interest normalized with respect to the motor rotational speed.

### Data Collection Process

In the following, for clarification purposes, certain steps of the methods as disclosed herein are described as part of a data collection process. It is to be understood that this data collection process may refer to an initial stage, wherein the traceable frequency components are determined for the purposes of subsequent anomaly detection, but also to subsequent stages, wherein the data collection process is ongoing while anomaly detection is already happening.

During the data collection process the sensor system may be used for collecting the raw three-phase voltages 304, 304′, 304″ and raw three-phase currents 303, 303′, 303″ for the purposes of determining a “normal” operation status, i.e. a kind of “normal” machine-spectrogram that corresponds to a healthy or normal operation of the drivetrain without any anomalies and for the purposes of determining the predefined set of frequency components that may be traced. In initial stages basically the same computer implemented steps may be used as during operation (while the anomaly detection is ongoing), at least up to the forming of the combined frequency spectrum, i.e. steps 401-405 of FIG. 4, which will be described in detail further below.

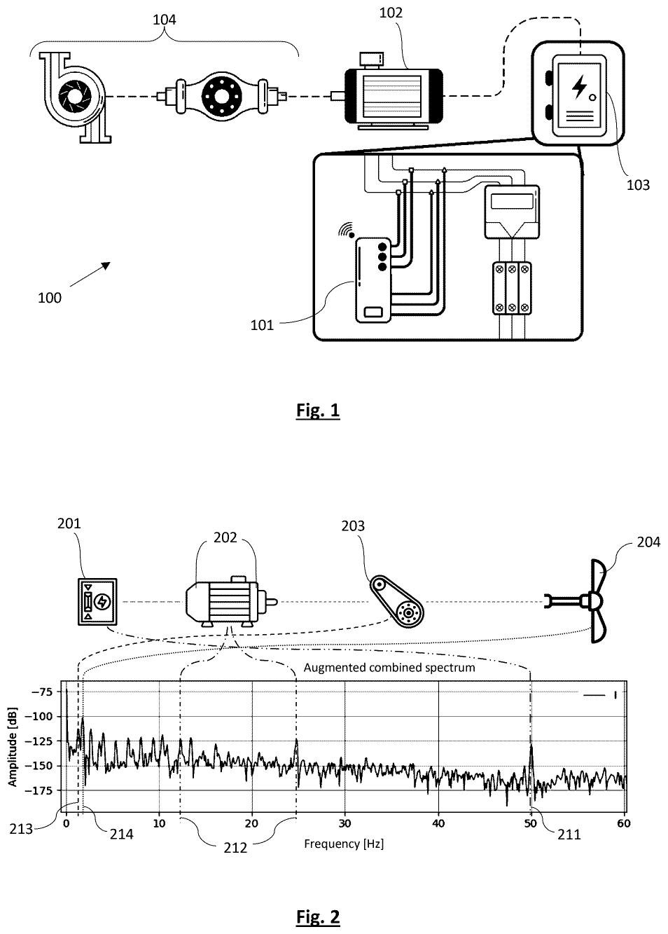

During the data collection process, raw voltage and current signals are captured and the raw data is communicated to the remote computing system for analysis. Data transformation steps are performed in order to obtain frequency spectra like the one shown in FIG. 2, which is an augmented combined frequency spectrum obtained at a particular timestamp from the raw electrical signals captured at the electric motor (after processing). The shown frequency spectrum comprises the following frequency components: a component 211 at 50 Hz which is related to the mains frequency of the power source 201; two components 212 which can be related to the rotating speed and the bearings 202 of the motor; one or more components 213 which can be related to couplings such as a drive belt 203; one or more components 214 which can be related to a load such as rotor blades or bearings of a ventilator 204. The relationship between the frequency components 212, 213, 214 and the mechanical elements 202, 203, 204 of the rotating machinery may be determined by using information such as machine metadata. In embodiments, the waveforms and/or frequency spectra may also be analysed by machine learning, wherein an AI model may be trained on large datasets of waveforms and/or frequency spectra relating to industrial drivetrains and subsequently used to recognize frequency components relating to mechanical elements of a drivetrain.

By the analysis that is performed during the initial stage, a predefined set of frequency components is determined that have a relationship with the mechanical elements during operation of the drivetrain, in particular to the vibrations caused by these mechanical elements that propagate along the drivetrain and are detectable in the voltage and current waveforms captured by the sensor system 101.

### Anomaly Detection Process

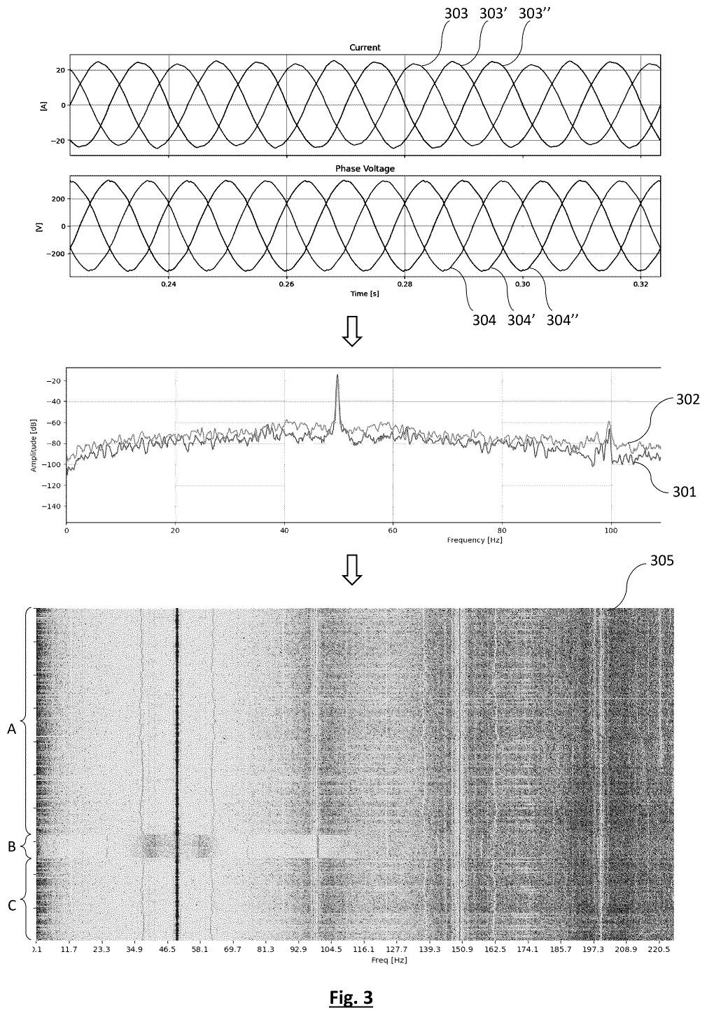

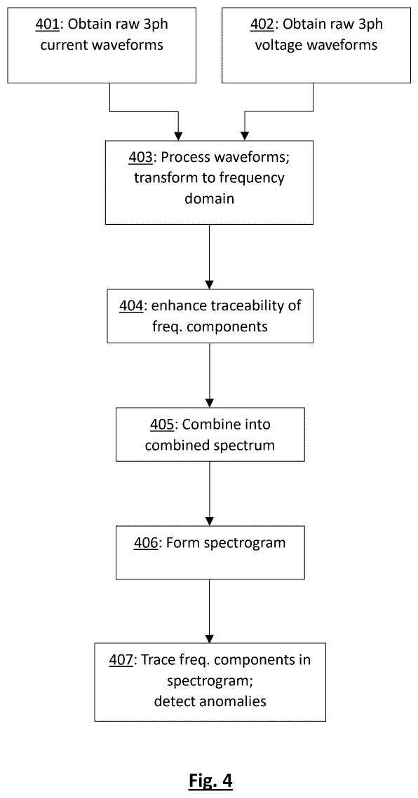

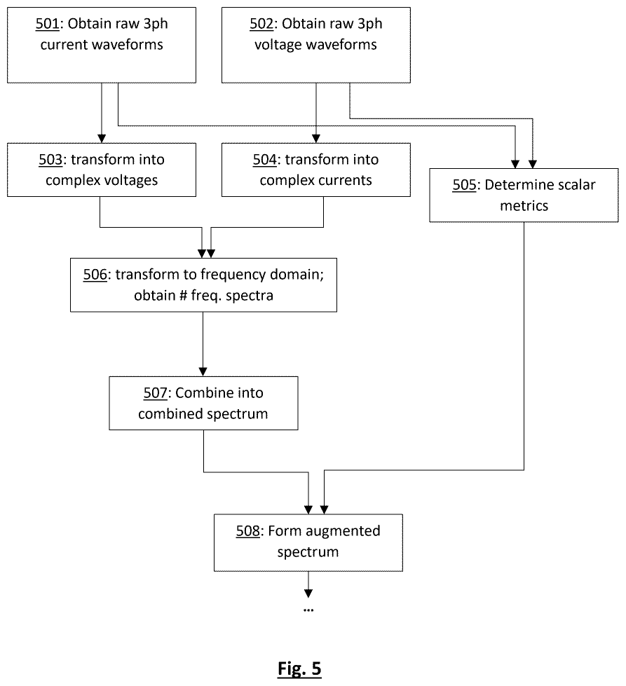

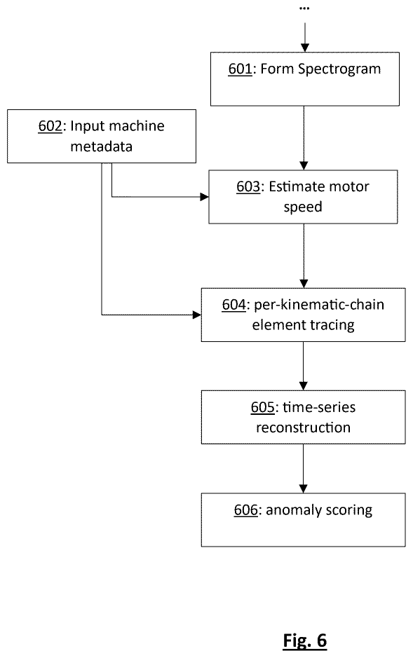

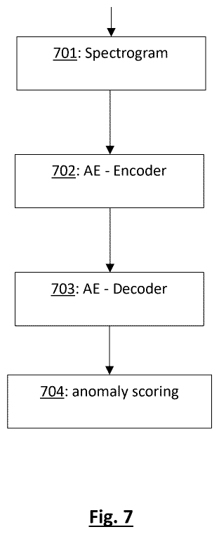

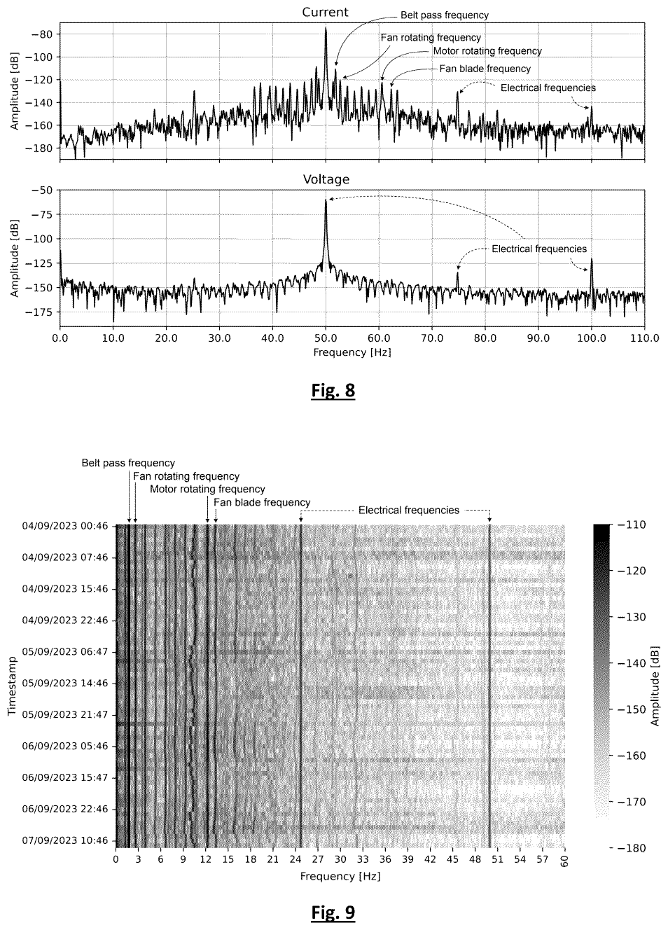

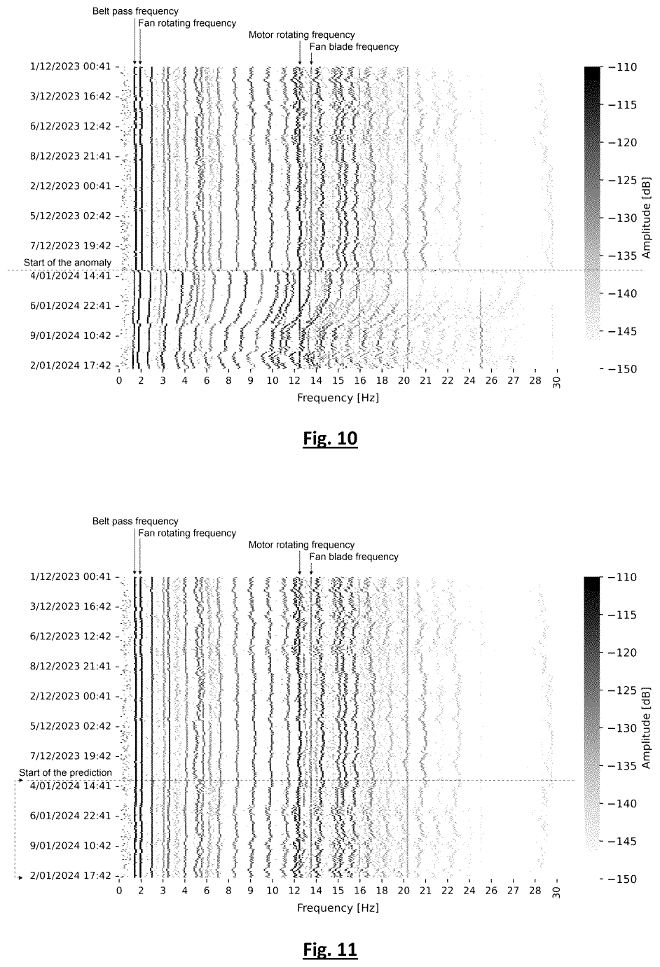

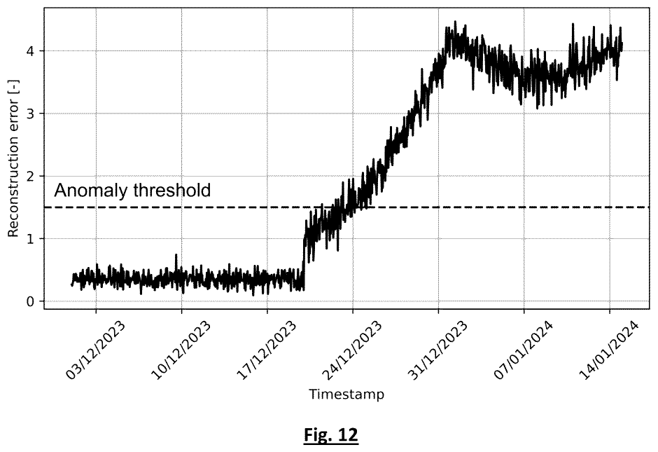

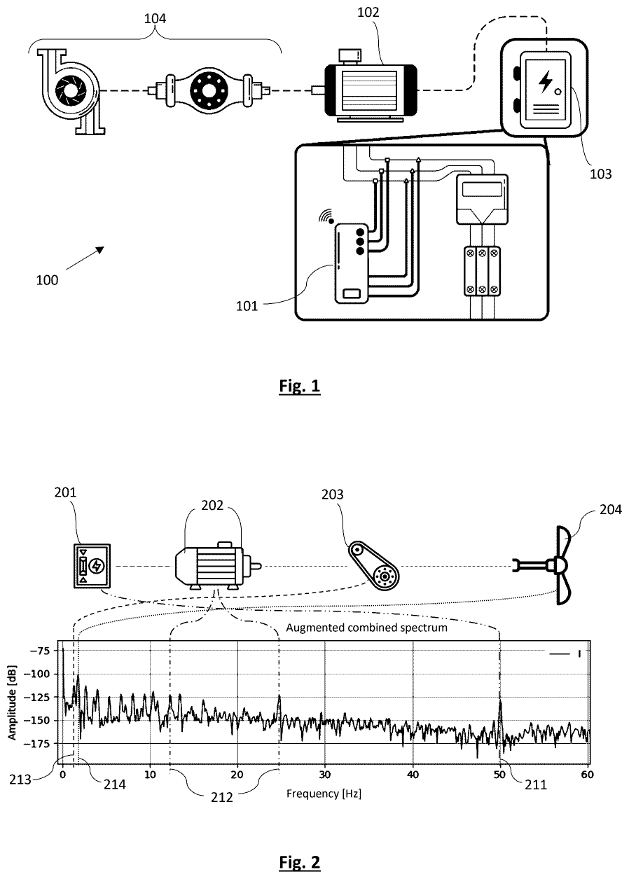

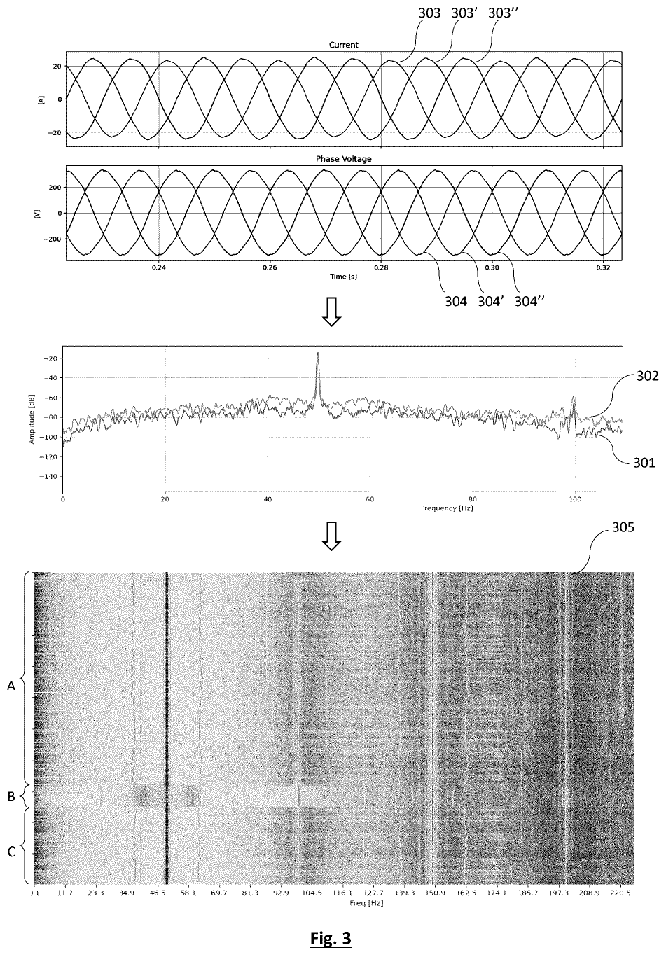

During the anomaly detection process the data collection is ongoing and raw voltage signals 304, 304′, 304″ and raw current signals 303, 303′, 303″ are captured and the raw data is communicated to the remote computing system for processing. FIG. 3 shows an example of what may happen during the anomaly detection process. The top of the figure shows a graph of captured three-phase current waveforms, 303, 303′, 303″ and three-phase voltage waveforms 304, 304′, 304″. These are processed, combined and possibly augmented (as described below) to obtain a combined spectrum, an example of which is shown in the middle of the figure. The combined spectrum is then monitored over time which gives a spectrogram 305, shown at the bottom of the figure. An anomaly is clearly visible in the spectrogram. During a first time period A the drivetrain is operating normally. The combined spectrum stays largely the same and corresponds to the lower curve 301 in the middle graph (the curve 301 is actually one sample in period A). During a second time period B an anomaly is detectable. There are significant changes in the combined spectrum, which now corresponds to the upper curve 302 in the middle graph (the curve 302 is one sample in period B). During a third period C, the anomaly is removed (e.g. after maintenance and/or repair to one or more elements of the drivetrain) and the operation is again normal, again corresponding to the lower curve 301.

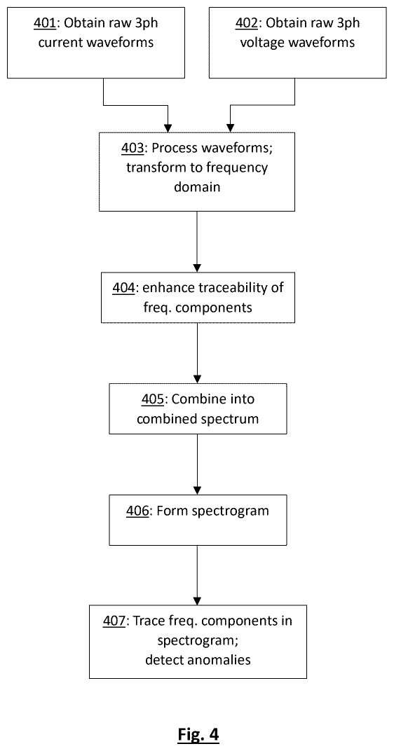

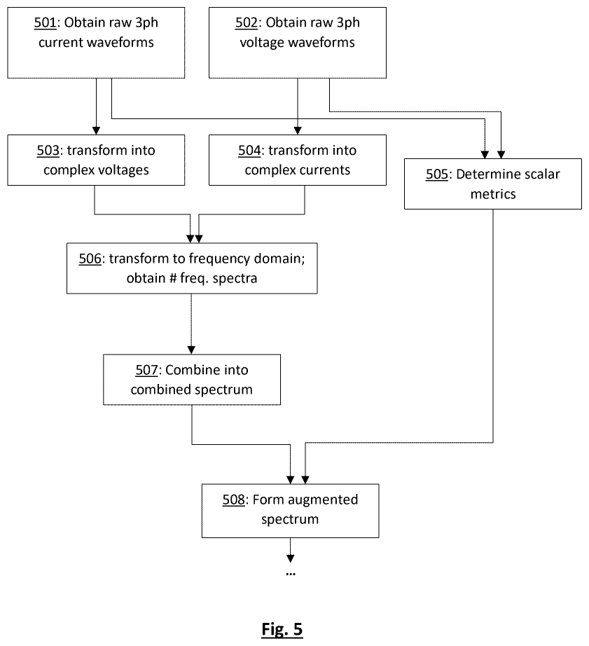

The anomaly detection process comprises steps 401-407 of FIG. 4 which will now be described in more detail. FIG. 5 shows a specific embodiment of some of the processing steps up to the forming of the combined/augmented spectrum (steps 403-405). FIGS. 6 and 7 show specific embodiments of the tracing of frequency components in the spectrogram and using them to detect and/or predict anomalies (step 407).

### Processing Steps

During the data collection, raw voltage and current signals are captured by the sensor system 101 and the raw data is communicated to the remote computing system for analysis or processing (steps 401 and 402 in FIG. 4; steps 501 and 502 in FIG. 5). The data collection may be a continuous process wherein data is collected sample-wise.

One or more processing steps 403-404 may be performed in order to enhance the traceability of the (desired) set of frequency components and/or to remove or diminish undesired frequency components (such as the mains frequency 211) in the collected raw data. The processing steps may for example include:
steps for transformation of the raw voltage and current waveform data into transformed voltages and transformed currents, for example by applying a direct-quadrature-zero transformation (steps 503 and 504 in FIG. 5);
conversion steps (step 403 in FIG. 4; step 506 in FIG. 5) for converting the (transformed) voltages and currents from the time domain to the frequency domain, for example by a discrete Fourier transformation (through an FFT algorithm);
filtering steps for filtering out undesired frequency components, such as for example noise originating from the power source 201;
data compression steps for keeping only the most significant frequency components in the frequency spectra.

The direct-quadrature-zero transformation is an operation which is known per se and combines the three individual voltage/current waveforms into transformed differential-mode waveforms (direct and quadrature) and one common-mode waveform (zero).

First frequency spectra are obtained from the (transformed) voltages and currents after transformation to the frequency domain (step 403; step 506).

In preferred embodiments, for example shown in FIG. 5, one or more steps 505 are included for computation of scalar metrics from the raw voltage and current signals. Examples of scalar metrics are the input active power, line frequency, switching frequency (in case the motor is supplied by a VFD), etc. These scalar metrics are calculated from the voltages and currents by mathematical formulae and may be used for augmenting the combined spectrum (step 508 in FIG. 5). For example, the input active power is computed as follows:

$${P}_{in} = mean ( {V}_{a} {I}_{a} + {V}_{b} {I}_{b} + {V}_{c} {I}_{c} )$$

with Vₐ, V_{b}, V_{c} the instantaneous values of the voltage waveforms and Iₐ, I_{b}, I_{c} the instantaneous values of the current waveforms. The line frequency is determined as the frequency component with the highest amplitude in the voltage spectrum. The switching frequency is determined in case of a motor supplied by a VFD as the frequency component with the highest amplitude in the zero-sequence voltage spectrum.

In step 405 (507 in FIG. 5), the obtained first frequency spectra, that are related to the transformed current and voltage waveforms, are combined into a combined spectrum, where some frequency components may be attenuated or amplified by combining current and voltage frequency spectra. This combined spectrum may further be augmented based on the scalar metrics (step 508) such as to improve the traceability of at least one frequency component. For example, the augmented spectrum may be normalized using the instantaneous line frequency and the nameplate line frequency. This technique is particularly useful for electric motors supplied by a variable frequency drive (VFD) that regularly changes the operating frequency of the motor. Furthermore, the augmented spectrum may be further normalized using the active power and the rated active power from the motor nameplate. This technique allows to realign the spectrum of electric motors operating at different torque levels, by supposing the torque-slip curve is linear close to the nominal operating point of the motor, and by neglecting the power losses, hence using the active power instead of the electromagnetic torque. Finally, an augmented combined spectrum with enhanced traceability of the frequency components is obtained.

For reducing storage space, a pre-compression step may be performed by using a lossy compression scheme on the augmented spectrum that is formed in step 508. One possibility is applying a peak detection algorithm and keeping only the M most prominent peaks, with M an integer parameter defining the amount of the compression loss.

### Tracing & Anomaly Detection

Next, a spectrogram is formed (step 406; step 508) by monitoring the augmented combined spectrum over time. This machine-spectrogram may be a multi-dimensional data object containing the frequencies and related amplitudes from the augmented spectrum, along with a timestamp for each collected data sample. A visual representation of a machine-spectrogram 305 is shown in FIG. 3. The spectrogram contains sufficient information to detect anomalies on the electric motor and its drivetrain. The calculated scalar metrics may also be stored sample wise along with the machine-spectrogram, as this data may be useful for anomaly detection, possibly in combination with the subsequent steps described below.

The spectrogram 305 may then be used for tracing the predefined set of frequency components in the spectrogram for anomaly detection of the related mechanical elements of the industrial drivetrain (step 407 in FIG. 4). In preferred embodiments, as the spectrogram may contain a lot of information on multiple dimensions, a compression algorithm may be applied to extract the most meaningful information that may lead to the detection of failures. The compression algorithm may be lossy and may reduce the dimensionality of the data to a lower-dimensional space such as to retain only the most meaningful properties of the data and better discriminate between a healthy (or “normal”) and unhealthy state, as well as to classify the default in case of an unhealthy state. The compression algorithm may be based on a physical method or based on a data-centric method.

In a first embodiment (physical method), shown in FIG. 6, the motor rotational speed is first estimated based on the machine-spectrogram 305 (steps 602-603), for which machine metadata is used. As opposed to other motor rotational speed detection methods that are based on a single spectrum taken during a single data collection step, this method is based on the complete history through the machine-spectrogram 305. First, the synchronous speed is determined based on the number of pole pairs (known from the machine metadata through the motor nameplate) and the line frequency (scalar metric). In the case that the electric motor is a synchronous motor, the motor speed is simply the synchronous speed. In the case that the electric motor is an induction motor (or asynchronous motor), the speed may be determined through inherent asymmetries of the motor. For example, due to the inherent asymmetries of the motor, a frequency component (succession of peaks) may be visible right below the synchronous speed in the machine-spectrogram 305, whereas a single peak may not be directly visible in a single augmented spectrum (at a single time stamp). A tracing algorithm may be used to precisely follow the frequency component related to the motor speed.

As mentioned above, the machine metadata may be any additional data about the particular electric motor 102 and its related drivetrain 104 that is not directly collected by the sensor system 101 and provides context. The metadata is static, i.e. does not evolve over time. It may provide information about the manufacturing and capabilities of the electric motor and its related drivetrain as well as the process they have been made to follow. The metadata may include motor nameplate information, as well as a list of all drivetrain elements along with their theoretical frequencies of interest normalized with respect to the motor rotational speed. Each drivetrain element has at least one frequency of interest. Examples include the “belt-pass frequency” for belt applications, the “gear mesh frequency” for gearbox or bearing-related fault indicators for bearing elements, etc. Each frequency ratio of interest is multiplied by the motor rotational speed to obtain the theoretical frequency. A tracing algorithm may then be used to precisely follow each frequency component of interest in the machine-spectrogram 305.

More in particular, each mechanical element of the drivetrain may have one or multiple theoretical frequencies related to it. The tracing algorithm matches the theoretical frequencies with the frequency components visible in the machine-spectrogram. It takes as input the theoretical frequency as well as a window size, and using the machine-spectrogram outputs one or multiple univariate time-series (step 604). These are used as parameters that are inputted into a univariate prediction model. In this way, a prediction for the next sample or samples of the machine-spectrogram may be determined. Anomalies may be detected by comparing these predicted samples with actual samples (step 605). A reconstruction error or anomaly score may thus be obtained (step 606). If the error exceeds a predefined threshold, an alert may be triggered.

A second embodiment (data-centric method) is shown in FIG. 7. Here, the need for physical information such as machine metadata may be avoided and the method may be purely based on previously collected data through the complete evolution of the machine-spectrogram 305 (multi-dimensional time series). In this embodiment, a machine learning model may be used, for example using a neural network, preferably an autoencoder. The final step of anomaly scoring (step 704) may be the same or similar to the first embodiment.

The autoencoder (AE) may be trained during a learning phase on historical data, i.e. a large dataset of machine-spectrograms, before being used in the evaluation phase. This way, the model may learn how to predict future (healthy) data through the encoder-decoder structure. The model may be used unsupervised because it does not require labeled data indicating where a fault occurred.

The AE encoder (step 702) may learn how to best reduce the dimension of the spectrogram 305 by using a deep neural network consisting of multiple convolutional layers producing a latent space that has a lower dimension than the input layer. The AE decoder (step 703) is the symmetrical reverse of the encoder. The output layer of the decoder has the same size as the input layer of the encoder, such as to reproduce the same data dimension.

During the training phase, the autoencoder adapts weights and biases in the different layers such as to reconstruct the input as best as possible. The reduced dimension of the latent space creates a bottleneck that forces the model to reconstruct the input based on a smaller dimension, forcing it to learn key representations or features in the high dimensional data.

Based on an input of N samples from the spectrogram, the output of the decoder generates a prediction of the future M healthy samples in this same spectrogram. This prediction is compared with the actual M samples. A reconstruction error is obtained (step 704) and if the error exceeds a certain threshold, or more generally does not respect a set of conditions, an anomaly is detected and an alert may be triggered.

### Practical Example

An industrial axial-flow fan is used to cool down a chemical reactor in a petrochemical plant. If, for any reason, the fan shuts down, the chemical reactor may need to be shut down, as well as the complete production line, since it cannot be effectively cooled down anymore. This may lead to very costly unplanned downtime for the plant. As a result, the fan is a critical piece of equipment and unplanned downtime should preferably be avoided.

The fan is driven by an electric three-phase induction motor through a belt-pulley system. A schematic representation of such a system of rotating machinery is shown in FIG. 2. The most important drivetrain elements in this example are:
The motor itself, with its nameplate indicating 4 poles and a rated power of 75 kW;
the two motor bearings, with reference 6319 (non-driving end) and NU316 (driving end);
the input (200 mm diameter) and output sheaves (1250 mm diameter), the V-belt of length 4750 mm. The ratio of the belt is therefore 6.25:1;
the axial-flow fan, with 4 blades;
the fan bearings, with reference 6310.

The collected metadata in this example includes the motor nameplate, the technical reference of the bearings, the belt length, sheaves diameters, and fan nameplate.

### Data Collection and Processing

A sensor system is installed in the motor control cabinet (MCC) for capturing raw electrical data, namely the raw voltage and raw current waveforms. After collecting the data, the raw electrical data is sent to a cloud environment, where the data is processed to form the machine-spectrogram as schematically shown in FIG. 3.

In particular, in the cloud environment, the voltages and currents are transformed into direct-quadrature-zero components, and transformed in the frequency-domain through an FFT algorithm to obtain first frequency spectra. FIG. 8 shows an example of such first frequency spectra obtained from the voltage and current waveforms. Detectable frequency components are indicated on the figure.

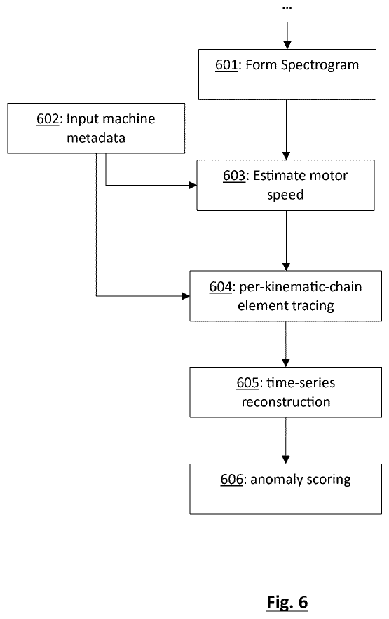

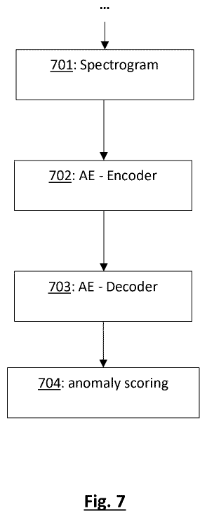

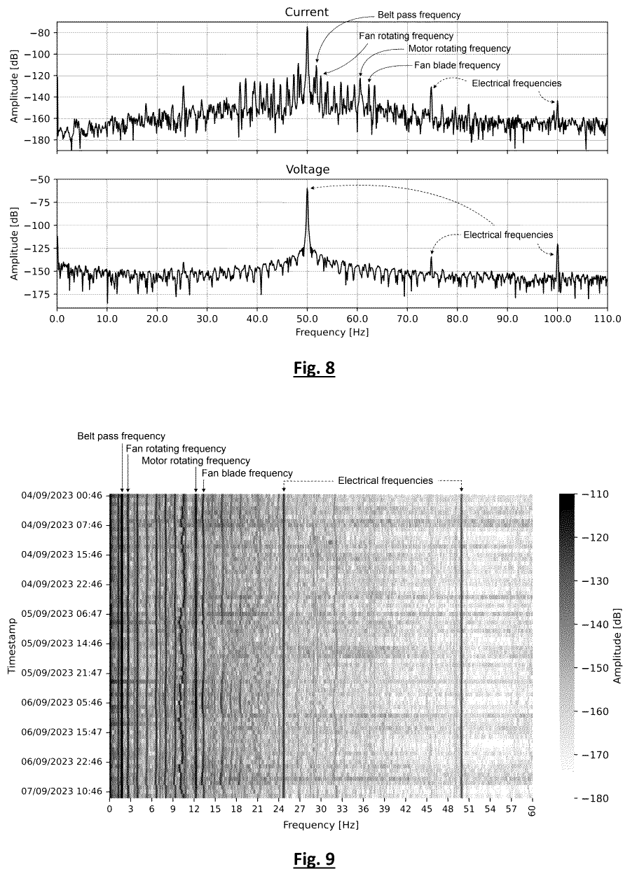

These first frequency spectra are combined into a combined spectrum such as to attenuate the frequency components related to unwanted electrical frequencies. Furthermore, the combined spectrum is normalized using the line frequency and the active power (scalar metrics), thus obtaining an augmented spectrum. The augmented spectrum is compressed by keeping only the 1000 most prominent peaks. The machine-spectrogram is formed by monitoring the (compressed) augmented spectrum over time. FIG. 9 shows a portion of the obtained machine-spectrogram. Detectable frequency components are indicated on the figure.

The anomaly detection based on the machine-spectrogram can be done using a physical approach or a data-centric approach.

### Physical (Compression) Approach

The frequency component related to the motor speed is determined through inherent asymmetries of the induction motor, by locating the peak just below the synchronous speed (known through the motor nameplate) in the machine-spectrogram. Based on the motor speed and metadata, the other theoretical frequencies related to mechanical elements of the drivetrain may be determined, namely:
The belt pass frequency: the frequency related to the speed of the belt passing on the sheaves:

$${f}_{bp} = {f}_{m} \frac{π {D}_{1}}{{L}_{b}} = 0.1 \; 32 {f}_{m}$$

wherein fₘ is the motor frequency, D₁ the diameter of the input sheave, L_{b} the length of the belt.
The fan rotating frequency: the frequency related to the speed of the fan:

$${f}_{f} = {f}_{m} \frac{{D}_{1}}{{D}_{2}} = 0.16 {f}_{m}$$

wherein D₁ is the diameter of the output sheave.
The fan blade frequency: the frequency related to the speed of blades of the fan:

$${f}_{f} = {f}_{m} \frac{{D}_{1}}{{D}_{2}} {N}_{b} = 0.64 {f}_{m}$$

wherein N_{b} is the number of fan blades.
The bearing frequencies of the motor and fan bearings: fault frequencies related to the specific bearing models. These can be categorized as inner raceway fault defect frequency, outer raceway fault defect and cage defect. Each of these frequencies are specific to the bearing reference. For example, for the 6319 bearing, these frequencies are:

$${f}_{bpfo} = 3.0 \; 96 {f}_{m} ( for the outer raceway defect )$$

$${f}_{bpfi} = 4.9 \; 04 {f}_{m} ( for the inner raceway defect )$$

$${f}_{ftf} = 0.3 \; 87 {f}_{m} ( for the cage defect )$$

The frequency components associated to these theoretical frequencies are to be traced on the motor-spectrogram (a portion of which is shown in FIG. 9). The tracing algorithm first determines if the frequency component is present in the motor-spectrogram based on a density-estimation method within a predefined window around the theoretical frequency. If the frequency component is deemed present, it is traced in the motor-spectrogram by taking the peak with the highest amplitude in the predefined window around the theoretical frequency. Every traced mechanical frequency component then outputs two univariate time-series: the evolution of its frequency over time and the evolution of its amplitude over time.

The scalar data obtained from the raw electrical measurements is also converted to univariate time-series, namely:
The evolution of active power over time
The evolution of line frequency over time
The evolution of power factor over time

The result is a set of at least 10 different univariate time-series that may be analyzed independently of each other, or in certain combinations. In this example, for every univariate time series, for a new data point its deviation is measured from the previous mean defined over the past N (256) points. The normality assumption can be checked by performing a Shapiro-Wilk test. With mean y and variance σ defined over the past N points, and x the (new) observed value, compute the standard z-score:

$$z = \frac{x - μ}{σ}$$

If the absolute value of this standard z-score is above a certain threshold (such as 2), then the data point belongs to the most extreme (5% for a threshold of 2) values. In this example, such extreme values are interpreted as anomalies.

An example of an anomaly that may occur on the rotating machinery described in this example is belt slip. In this case, the belt starts slipping on the sheaves which reduces the efficiency of the cooling process, and may lead to the complete destruction of the belt, resulting in the failure of the equipment. Such an anomaly is visible in the machine-spectrogram presented in FIG. 10. The tracing of the belt pass frequency and load frequency are good indicators for such an anomaly.

### Data-Centric Approach

The complete machine-spectrogram is given as input to a previously trained autoencoder. Sparsity in the machine-spectrogram is high due to the compression scheme applied previously. Lost values due to compression are assigned the minimum values of the observation data. Values of amplitudes are min-max scaled to range [0, 1]. The autoencoder consists of an encoder structure having 6 blocks each containing a convolutional layer, a batch normalization, and an activation function and a decoder structure having 6 blocks each containing a transposed convolutional layer, a batch normalization, and an activation function. From the complete motor-spectrogram, only the most recent 320 (256+64) samples are kept. The oldest 256 samples are given as input to the previously trained autoencoder. The output of the autoencoder generates a prediction of the expected future 64 healthy samples of the motor-spectrogram. This prediction is compared with the actual known remaining 64 samples. A reconstruction error on the 64 samples is obtained by subtracting the expected values with the actual values. If the error exceeds a certain predetermined threshold, an anomaly is considered as detected and an alarm may be raised.

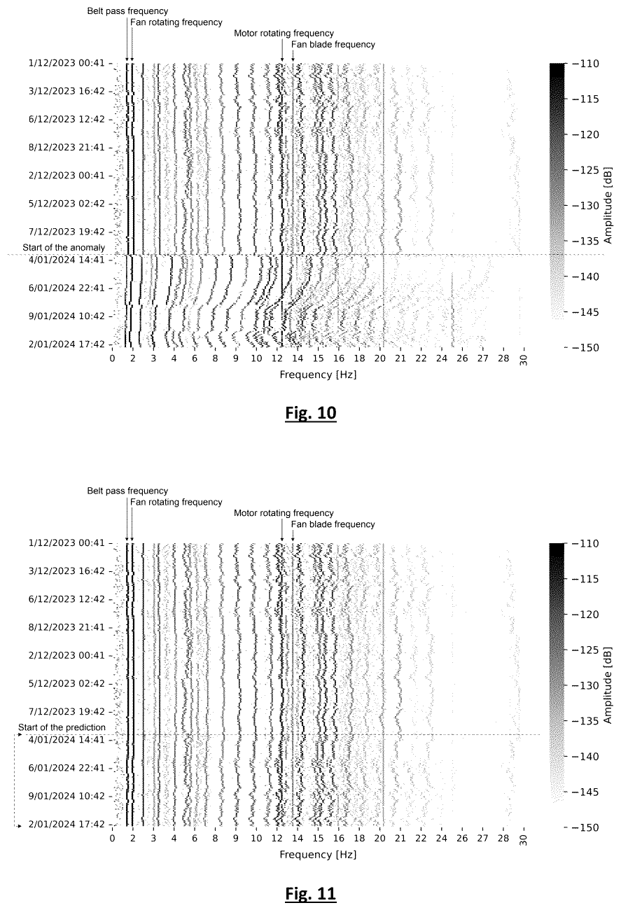

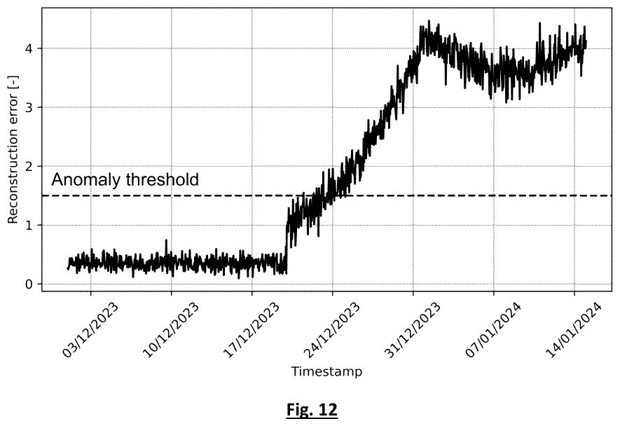

This process is illustrated by means of FIGS. 10-12. FIG. 10 shows the machine-spectrogram, with a healthy part (top of the figure) and an anomaly (bottom of the figure). The start of the anomaly is indicated by the dashed line. By giving the healthy part of the machine-spectrogram as input to the trained autoencoder, it will predict a complete healthy machine-spectrogram as shown in FIG. 11. This figure shows a reconstructed spectrogram that is outputted by the trained autoencoder. The top part of the reconstructed spectrogram is reconstructed from the healthy part of the machine-spectrogram of FIG. 10; the bottom part of the reconstructed spectrogram is a prediction of the machine-spectrogram generated by the autoencoder. For the anomaly detection, the prediction of the autoencoder is then compared to the original (anomalous) machine-spectrogram and the reconstruction error is computed. The reconstruction error may be represented as a univariate time-series. Once the reconstruction error exceeds a certain predefined threshold, the anomaly is raised. FIG. 12 shows a graph of this reconstruction error. As shown, the error increases at the anomaly and once the anomaly threshold is exceeded, an alarm may be raised.

1. A system for anomaly detection in an industrial drivetrain, wherein the industrial drivetrain comprises various mechanical elements and is driven by a three-phase electrical motor, the system comprising:
a sensor system for obtaining electrical current and voltage waveform data by measuring electrical currents and voltages at the three-phase motor, the electrical current and voltage waveform data containing a predefined set of frequency components relating to vibrations of a number of said mechanical elements during operation of the drivetrain; and
a computing system configured for performing the following steps:
processing the electrical current and voltage waveform data to obtain a number of frequency spectra related to the waveform data, wherein the processing comprises steps for enhancing traceability of the frequency components in said frequency spectra;
combining the frequency spectra to a combined frequency spectrum, wherein the combining step further enhances traceability of the frequency components in the combined frequency spectrum;
forming a spectrogram by monitoring the combined frequency spectrum over time; and
detecting anomalies of the predefined set of frequency components in the spectrogram for anomaly detection of the related mechanical elements of the industrial drivetrain.

2. The system of claim 1, wherein the computing system is at least partially integrated with the sensor system in a sensor unit that is located at or near the three-phase motor.

3. The system of claim 1, wherein the computing system is a remote computing system and wherein the sensor system is provided for communicating with the remote computing system.

4. The system of claim 1, wherein the obtained frequency spectra at least partially overlap and wherein the step of combining the frequency spectra to the combined frequency spectrum amplifies at least some of the frequency components.

5. The system of claim 1, wherein the frequency components relate to vibrations caused by one or more of the following group of mechanical elements:
couplings such as a V-belt, a timed belt, a chain, a cardan joint, a rigid coupling, a flexible coupling, a jaw coupling, a magnetic coupling or other coupling element;
single- and multi-staged gearboxes;
mechanical loads such as a pump, a submersible pump, a compressor, a ventilator, a mixer, a conveyor belt, a crusher, an elevator, a vibrating screen, a worm screw, a blower, or other mechanical load element.

6. The system of claim 1, wherein the processing steps comprise one or more of the following: direct quadrature zero transformation; direct Fourier transformation; Hilbert transform; filtering, amplification and/or attenuation to improve a signal to noise ratio of at least one of the frequency components; data compression steps for removing less significant data.

7. The system of claim 1, wherein the processing steps comprise computation of one or more scalar metrics, and wherein the processing steps comprise one or more steps for augmenting the combined frequency spectrum based on the one or more scalar metrics, preferably wherein the scalar metrics comprise at least one of: active power, reactive power, line frequency, switching frequency.

8. The system of claim 1, wherein the computing system is further configured for performing one or more data compression steps for compression of the spectrogram, preferably wherein the spectrogram is compressed by means of a lossy compression algorithm.

9. The system of claim 1, wherein the computing system is configured for detecting anomalies by tracing the predefined set of frequency components in the spectrogram.

10. The system of claim 9, wherein the step of tracing the frequency components in the spectrogram comprises: detecting and tracing a motor rotational speed of the electrical motor in the spectrogram, determining a frequency ratio of each of the predefined set of frequency components with respect to the motor rotational speed, and tracing the frequency components based on the determined frequency ratios.

11. The system of claim 9, wherein the computing system is further configured for performing the following steps for the anomaly detection: comparing traced values of the traced frequency components with predicted values of the frequency components, calculating an anomaly score based on the comparison and triggering an alert if the anomaly score meets predetermined conditions.

12. The system of claim 1, wherein the computing system is configured for detecting anomalies by using a machine learning model on the spectrogram, preferably a trained autoencoder.

13. The system of claim 12, wherein the computing system uses the machine learning model to predict values for the predefined set of frequency components, and wherein the computing system is configured to compare the predicted values with actual values of the predefined set of frequency components, calculate an anomaly score based on the comparison and trigger an alert if the anomaly score meets predetermined conditions.

14. A computer implemented method for anomaly detection in an industrial drivetrain, wherein the industrial drivetrain comprises various mechanical elements and is driven by a three-phase electrical motor, the method comprising the steps of:
obtaining electrical current and voltage waveform data from a sensor system measuring electrical currents and voltages at the three-phase motor, the electrical current and voltage waveform data containing a predefined set of frequency components relating to vibrations of a number of said mechanical elements during operation of the drivetrain;
processing the electrical current and voltage waveform data to obtain a number of frequency spectra related to the waveform data, wherein the processing comprises steps for enhancing traceability of the frequency components in said frequency spectra;
combining the frequency spectra to a combined frequency spectrum, wherein the combining step further enhances traceability of the frequency components in the combined frequency spectrum;
forming a spectrogram by monitoring the combined frequency spectrum over time; and
detecting anomalies of the predefined set of frequency components in the spectrogram for anomaly detection of the related mechanical elements of the industrial drivetrain.

15. The computer implemented method according to claim 14, wherein the obtained frequency spectra at least partially overlap and wherein the step of combining the frequency spectra to the combined frequency spectrum amplifies at least some of the frequency components.

16. The computer implemented method according to claim 14, wherein the frequency components relate to vibrations caused by one or more of the following group of mechanical elements:
couplings such as a V-belt, a timed belt, a chain, a cardan joint, a rigid coupling, a flexible coupling, a jaw coupling, a magnetic coupling or other coupling element;
single- and multi-staged gearboxes;
mechanical loads such as a pump, a submersible pump, a compressor, a ventilator, a mixer, a conveyor belt, a crusher, an elevator, a vibrating screen, a worm screw, a blower, or other mechanical load element.

17. The computer implemented method according to claim 14, wherein the processing steps comprise one or more of the following: direct quadrature zero transformation; direct Fourier transformation; Hilbert transform; filtering, amplification and/or attenuation to improve a signal to noise ratio of at least one of the frequency components; data compression steps for removing less significant data.

18. The computer implemented method according to claim 14, wherein the processing steps comprise computation of one or more scalar metrics, and wherein the processing steps comprise one or more steps for augmenting the combined frequency spectrum based on the one or more scalar metrics, preferably wherein the scalar metrics comprise at least one of: active power, reactive power, line frequency, switching frequency.

19. The computer implemented method according to claim 14, further comprising one or more data compression steps for compression of the spectrogram, preferably wherein the spectrogram is compressed by means of a lossy compression algorithm.

20. The computer implemented method according to claim 14, wherein the step of detecting anomalies comprises tracing the predefined set of frequency components in the spectrogram.

21. The computer implemented method according to claim 20, wherein the step of tracing the frequency components in the spectrogram comprises: detecting and tracing a motor rotational speed of the electrical motor in the spectrogram, determining a frequency ratio of each of the predefined set of frequency components with respect to the motor rotational speed, and tracing the frequency components based on the determined frequency ratios.

22. The computer implemented method according to claim 20, further comprising the following steps for the anomaly detection: comparing traced values of the traced frequency components with predicted values of the frequency components, calculating an anomaly score based on the comparison and triggering an alert if the anomaly score meets predetermined conditions.

23. The computer implemented method according to claim 14, wherein the step of detecting anomalies comprises using a machine learning model on the spectrogram, preferably a trained autoencoder.

24. The computer implemented method according to claim 23, wherein the machine learning model is used to predict values for the predefined set of frequency components, and wherein the method further comprises comparing the predicted values with actual values of the predefined set of frequency components, calculating an anomaly score based on the comparison and triggering an alert if the anomaly score meets predetermined conditions.

25. A non-transitory computer-readable medium containing code in a computer executable format which when executed on a computing system triggers the computing system to perform the computer-implemented method of claim 14.
